(19) United States
(12) Patent Application Publication
(10) Pub. No.: US 2010/0200991 A1
(43) Pub. Date: Aug. 12, 2010

(54) Dopant Enhanced Interconnect

(76) Inventors: Rohan Akolkar, Hillsboro, OR (US); Sridhar Balakrishnan, Portland, OR (US); Adrien R. Lavoie, Beaverton, OR (US); Tejaswi K. Indukuri, Hillsboro, OR (US); James S. Clarke, Portland, OR (US)

Correspondence Address: GROSSMAN, TUCKER, PERREAULT & PFLEGER, PLLC;c/o CPA Global, P. O. BOX 52050, MINNEAPOLIS, MN, 55402, US

(21) Appl. No.: 12/705,143

(22) Filed: Feb. 12, 2010

Related U.S. Application Data
(63) Continuation-in-part of application No. 11/724,361, filed on Mar. 15, 2007, now abandoned.

(51) Int. Cl. H01L 23/532; H01L 21/768

(52) U.S. Cl. 257/751; 438/643; 257/E23.161; 257/E21.584

(57) ABSTRACT

Techniques are disclosed that enable an interconnect structure that is resistance to electromigration. A liner is deployed underneath a seed layer of the structure. The liner can be a thin continuous and conformal layer, and may also limit oxidation of an underlying barrier (or other underlying surface). A dopant that is compatible (non-alloying, non-reactive) with the liner is provided to alloy the seed layer, and allows for dopant segregation at the interface at the top of the seed layer. Thus, electromigration performance is improved.

### RELATED APPLICATION

This application is a continuation-in-part of U.S. application Ser. No. 11/724,361 filed Mar. 15, 2007, which is herein incorporated by reference in its entirety.

### BACKGROUND

In the manufacture of integrated circuits, copper interconnects are generally formed on a semiconductor substrate using a copper dual damascene process. Such a process typically begins with a trench being etched into a dielectric layer and filled with a barrier layer, an adhesion layer, and a seed layer. A physical vapor deposition (PVD) process, such as a sputtering process, may be used to deposit a tantalum nitride (TaN) barrier layer, and a tantalum (Ta) or ruthenium (Ru) adhesion layer (i.e., a TaN/Ta or TaN/Ru stack) into the trench. This may be followed by a PVD sputter process to deposit a copper seed layer into the trench. The TaN barrier layer prevents the copper from diffusing into the underlying dielectric layer. The Ta or Ru adhesion layer is required because the subsequently deposited copper does not readily nucleate on the TaN barrier layer. An electroplating process is then used to fill the trench with copper metal to form the interconnect.

As device dimensions scale down, the aspect ratio of the trench becomes more aggressive as the trench becomes narrower. The line-of-sight PVD process gives rise to issues such as trench overhang of the barrier, adhesion, and seed layers, leading to pinched-off trench and via openings during plating and inadequate gapfill. Additionally, for very thin films (e.g., less than 5 nm thick) on patterned structures, thickness and composition control in PVD is difficult. For instance, for very thin layers the sputter time tends to be low, resulting in different thicknesses on wafer and sidewalls. In addition, early fail electromigration tends to become more of a problematic issue. One approach to addressing these issues is to reduce the thickness of the TaN/Ta or TaN/Ru stack, which widens the available gap for subsequent metallization. Unfortunately, this is often limited by the non-conformal characteristic of PVD deposition techniques.

### BRIEF DESCRIPTION OF THE DRAWINGS

FIG. 1 illustrates formation of an example via and trench recess for an interconnect structure configured in accordance with an embodiment of the present invention.

FIG. 2 illustrates deposition of a barrier layer and a liner on the via/trench recess of FIG. 1, in accordance with an embodiment of the present invention.

FIG. 3 illustrates formation of an alloyed seed layer on the liner of the structure of FIG. 2, in accordance with an embodiment of the present invention.

FIG. 4 illustrates one such example case, and shows deposition of an interconnect fill metal to fill the via and trench of the structure of FIG. 3, in accordance with an embodiment of the present invention.

FIG. 5 illustrates planarization of the structure of FIG. 4, in accordance with an embodiment of the present invention.

FIG. 6 illustrates formation of an etch stop layer and segregation of dopant material included in the alloyed seed layer along the etch stop layer interface the structure of FIG. 5, in accordance with an embodiment of the present invention.

FIG. 7 illustrates a method for forming a dopant enhanced interconnect in accordance with an embodiment of the present invention.

### DETAILED DESCRIPTION

Techniques are disclosed that enable an interconnect device that is resistance to electromigration. A liner is deployed, for example, between the barrier and seed layers of the structure. The liner can be a thin continuous and conformal layer, and may also limit oxidation of the underlying barrier (or other underlying surface). A dopant that is compatible (non-alloying, non-reactive) with the liner is provided to alloy the seed layer, and allows for dopant segregation into the interconnect fill metal, including along the top surface of the interconnect. Thus, electromigration performance of the interconnect device is improved.

General Overview

As previously explained, conventional interconnect processing involves barrier and copper seed layer deposition, followed by an electroplated gapfill process. The scaling of such conventional processes is limited because of available real-estate and PVD line-of-sight problems (e.g., overhang, etc). In addition, conventional electromigration dopants (such as aluminum) are not compatible with Ru because they alloy with Ru or form intermetallics, and therefore cannot segregate at the etch stop (or other protection layer) interface at the top of the interconnect.

Thus, and in accordance with an embodiment of the present invention, a Ru liner process is provided for an interconnect process. The Ru liner can be interjected, for example, between the barrier layer and a copper seed layer using atomic layer deposition (ALD) or chemical vapor deposition (CVD). A dopant that does not alloy or react with the Ru liner is used to alloy the copper seed layer. The dopant can be, for example, manganese (Mn) or magnesium (Mg), or other suitable dopant that does not alloy or react with the Ru liner (or other liner material).

The integrated use of dopants such as Mn and Mg in a Ru lined copper interconnect allows for improved electromigration performance and gapfill. In addition, interconnect scaling to nano-scale (and smaller) is enabled. The techniques can be used, for example, in fabricating interconnects for integrated circuits (both inter-chip and intra-chip interconnects) and components such as transistors. The interconnect structure may be implemented, for example, as a single or dual damascene structure. As is known, a dual damascene structure is an interconnect structure where the metal lines (or trenches) and the underlying vias are metallized in a single metal deposition, which is generally more efficient to fabricate than a single damascene structure which typically requires additional metal deposition, chemical mechanical polishing (CMP), and dielectric-deposition processing.

A cross-section of an interconnect fabricated in accordance with one example embodiment of the present invention shows, for instance, a copper interconnect structure having Mn or Mg in proximity to a top surface of the interconnect. An ALD/CVD Ru liner process in accordance with one such embodiment can be used to provide a continuous Ru film with improved Ru liner sidewall smoothness, relative to conventional processing. In addition, dopant segregation is allowed at the top surface of the copper seed layer/interconnect, which in turn allows for dopant-enhanced interconnect performance by inhibiting electromigration at that surface.

While specific embodiments of interconnect fabrication processes and structures provided herein include, for instance, a Ru liner used in conjunction with a copper seed layer alloyed with dopants Mg and/or Mn, other dopant-liner-interconnect material schemes will be apparent in light of this disclosure and the claimed invention is not intended to be limited to interconnect structures configured with a Mg/Mn—Ru-Copper scheme. In addition, various example processing techniques are provided herein (e.g., ALD, CVD, electrodeposition, electroless deposition, etc) but other suitable processing techniques may also be used to provide interconnect structures fabricated with a seed layer that is alloyed with a dopant that does not alloy or react with an underlying liner material, in accordance with an embodiment of the present invention.

Interconnect Structure

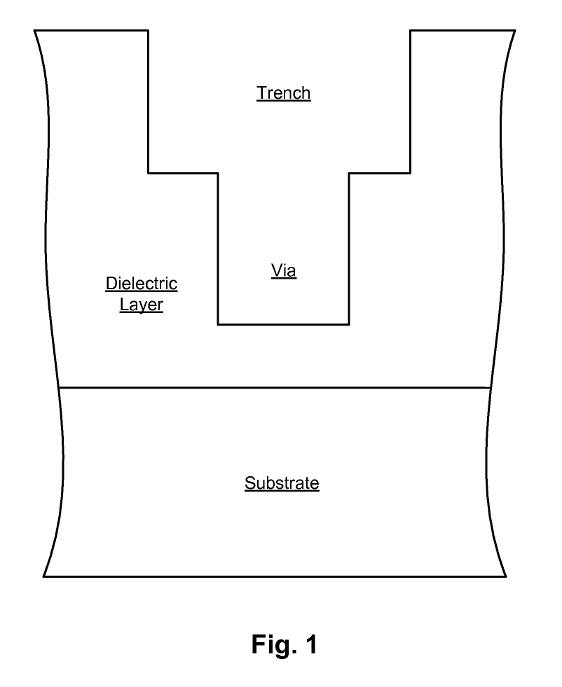

FIG. 1 illustrates formation of an example via and trench recess for an interconnect structure configured in accordance with an embodiment of the present invention. As can be seen in the cross-section side view, a dual damascene structure is fabricated in a dielectric layer deposited on a substrate. Other interconnect structures (e.g., single damascene) can equally benefit from an embodiment of the present invention, as will be appreciated in light of this disclosure.

The trench and via can be formed in the dielectric layer, for example, using standard lithography including via and trench patterning and subsequent etch processes followed by polishing, cleans, etc, as typically done. The patterning and etch processes can be carried out, for instance, using wet and/or dry etch techniques. The trench and via dimensions can vary, depending on the application. In one example case, the trench opening is about 10 nm to 100 nm (e.g., 20 to 50 nm) and the via opening is about 5 nm to 50 nm (e.g., 10 to 25 nm), and the entire structure has an aspect ratio in the range of about 8:1 to 2:1 (e.g., 4:1). As will be appreciated, the trench and via dimensions and aspect ratio of the structure will vary from one embodiment to the next, and the claimed invention is not intended to be limited to any particular range of dimensions.

The substrate may be implemented as typically done, and any number of suitable substrate types and materials can be used here. The substrate may be, for example, a bulk semiconductor wafer (e.g., bulk silicon, germanium, gallium arsenide or other III-V materials, etc) or an on-insulator configuration (e.g., silicon on-insulator, germanium on-insulator, silicon germanium on-insulator, indium phosphide on-insulator, etc). The substrate may be p-type, n-type, neutral-type, high or low resistivity, off-cut or not off-cut, etc. The substrate may have a vicinal surface that is prepared by off-cutting the substrate from an ingot, wherein substrate is off-cut at an angle between, for instance, 2° and 8° (e.g., 4° off-cut silicon). Note, however, the substrate need not have any such specific features, and that the interconnect structure can be implemented on numerous substrates. The substrate thickness can vary and in some embodiments, for example, is in the range of 100 nm to thousands of nanometers. In some cases, the substrate may be subsequently thinned or removed (e.g., by way of backside polish or other suitable thinning/removal process), after formation of the interconnect structure and application of protective layer such as etch stop, passivation layer, inter-layer dielectric (ILD), capping layer, etc.

The dielectric layer may include any number of conventional dielectric materials commonly used in integrated circuit applications, such as oxides (e.g., silicon dioxide, carbon doped oxide), silicon nitride, or organic polymers (e.g., perfluorocyclobutane or polytetrafluoroethylene), fluorosilicate glass, and organosilicates (e.g., silsesquioxane, siloxane, or organosilicate glass). The dielectric material may be low-k or high-k depending on the desired isolation, and may include pores or other voids to further reduce its dielectric constant. Although only one trench/via structure is shown, the dielectric layer may include multiple such structures. The dielectric layer thickness can vary and in some example embodiments is in the range of 50 nm to 5000 nm.

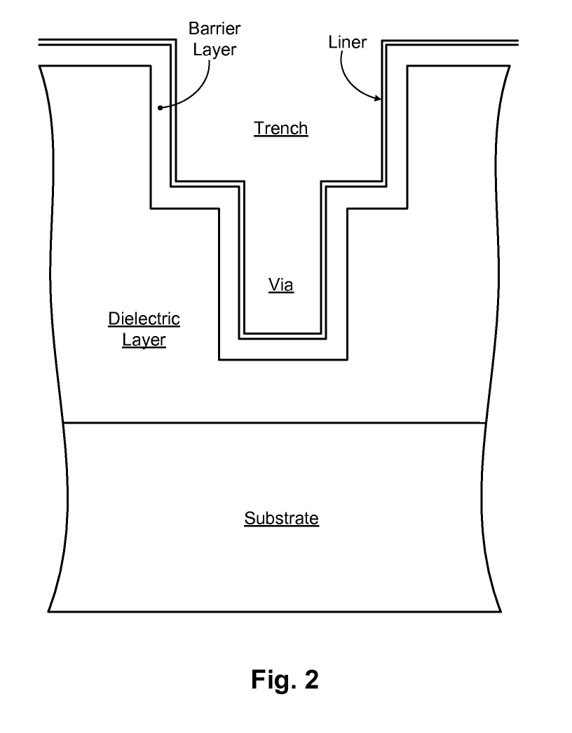

FIG. 2 illustrates deposition of a barrier layer and a liner on the via/trench recess of FIG. 1, in accordance with an embodiment of the present invention. In one example case, a barrier layer of tantalum (Ta), tantalum nitride (TaN), titanium (Ti), titanium nitride (TiN), or combinations thereof is deposited using CVD or ALD (or other suitable deposition technique), to provide a continuous and conformal barrier layer. The thickness of the barrier layer can vary, and in some such embodiments is in the range of 1 nm to 10 nm (e.g., 3 to 6 nm). In a more general sense, any barrier layer thickness sufficient to prevent the seed layer metal from diffusing into the dielectric layer can be used. The liner can then be deposited using CVD or ALD (or other suitable deposition technique), and can be, for example, ruthenium (Ru), cobalt (Co), nickel (Ni), or other material with which the seed layer dopant will not alloy or react. In some example such cases, the liner is deposited using ALD to provide a continuous and conformal liner layer in the range of 1 nm to 5 nm (e.g., 2 to 3 nm). As previously explained, the liner provides a relatively thin continuous and conformal layer relative to conventional PVD processing, and is highly noble and therefore limits oxidation of the underlying barrier layer. As will be explained in turn, a dopant that is compatible (non-alloying, non-reactive) with the liner is provided to alloy the seed layer, and allows for dopant segregation at the etch stop (or other protection layer) interface at the top of the seed layer. Note that the barrier and liner layers can be deposited in the same tool without air break. Further note that other embodiments may not have a barrier layer, as the barrier function can be integrated into other parts of the interconnect structure, such as within the liner or the seed layer itself. For example, if a Cu—Mn alloyed seed layer is provided (as discussed herein), the barrier layer may be eliminated. This is because the Cu—Mn alloy layer may provide the barrier functionality.

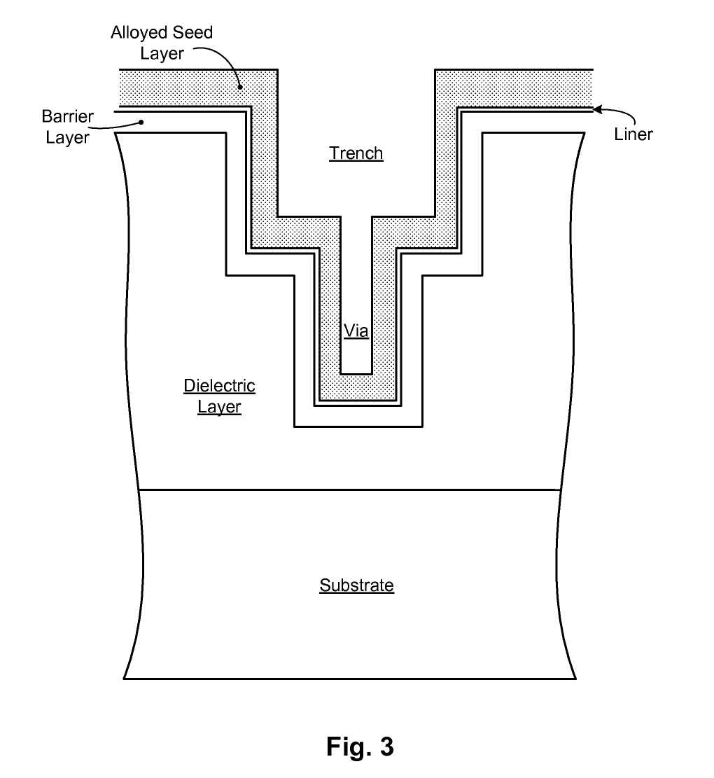

FIG. 3 illustrates formation of an alloyed seed layer on the liner of the structure of FIG. 2, in accordance with an embodiment of the present invention. The seed layer can be deposited on the liner, for example, using PVD, CVD or ALD (including plasma enhanced ALD, or PEALD) processes, or any other suitable deposition technique. As can further be seen, the seed layer is alloyed with a dopant that will not alloy or react with the liner. The presence of the alloying metal inhibits electromigration of the seed layer metal (such as copper). In some embodiments, the alloyed seed layer is deposited using ALD to provide a conformal seed layer in the range of 1 nm to 50 nm (e.g., 1 to 15 nm) that may be continuous or discontinuous, depending on given application.

Pre-Alloyed Seed Layer

In one specific example embodiment, an alloyed copper (Cu) seed layer is deposited on a Ru liner using a PVD process. The Cu to be deposited is effectively pre-alloyed in that it includes a percentage of Mn or Mg (or other suitable dopant that will not alloy or react with the Ru liner). As previously explained, these elements effectively serve as seed layer dopants to fix reliability of the copper interconnect structure. The percentage of the dopant content can vary, but in some embodiments is in the range of 3% to 15% (e.g., 5% Mg, or 5% Mn, or a hybrid dopant content of 2.5% Mn and 2.5% Mg). In any such cases, the PVD sputtering process generally yields a conformal layer of the alloyed seed material. The alloyed seed layer may have a thickness, for example, in the range of 1 nm to 30 nm (e.g., 10 nm to 15 nm), and may be continuous or discontinuous on the via and/or trench sidewall. For instance, and in accordance with one example embodiment, a copper seed layer alloyed with Mn or Mg is deposited in a discontinuous fashion, thereby exposing portions of an underlying Ru liner.

Alloyed Seed Layer by Layering

In another specific example embodiment, the alloyed seed layer can be deposited in a layered fashion using a PEALD process, where a layer of Cu is deposited and then a layer of Mg and/or Mn is deposited. This layering process can be repeated a number of times to provide alternating layers of Cu and Mg and/or Mn. The thickness of each of these layers can vary from one embodiment to the next, but in some example cases may range from 0.5 nm to 20 nm (e.g., 2-5 nm for each layer, or 2-5 nm for each Cu layer and 1-3 nm for each Mn/Mg layer). After deposition of the alternating layers is completed, the stack of layers can be annealed to combine the layer into either a homogenous or graded alloyed seed layer. The anneal can be carried out, for example, at a temperature in the range of 50° C. to 400° C. for a time duration that may last from 5 seconds to 1200 seconds, and may take place in an oxygen free ambient atmosphere, such as forming gas or a pure inert gas. During the anneal, the alloy metal layers and the copper metal layers intermix or diffuse together to merge and form the alloyed seed layer. Other annealing schemes will be apparent in light of this disclosure. In any such cases, a PEALD process can be used to provide a conformal and continuous alloy layer and allows for precise control over the thickness of the Cu-alloy seed layer (by way of the number of PEALD pulses), and over the tailoring or composition of the Cu-alloy seed layer (e.g., by way of modifying the precursors and/or co-reactants used in each PEALD pulse). Note that other embodiments need not employ PEALD, and may use any suitable PVD, CVD or ALD processes as previously explained. Further note that the alloyed seed layer can be continuous or discontinuous on the via and/or trench sidewall.

In some layered implementations, the alloyed seed layer may be homogenous across its thickness. For instance, assuming a copper seed layer alloyed with Mn or Mg in accordance with one example, the concentration of copper and the alloy metal may be homogenous throughout the alloyed seed layer. Alternatively, the alloyed seed layer may be a graded layer. For example, assuming a copper seed layer alloyed with Mn or Mg, the copper content may have a concentration gradient across the thickness of the copper seed layer, and/or the alloy metal Mn/Mg may have a concentration gradient across the thickness of the copper seed layer. In one such case, a first portion of a graded Cu-alloy seed layer proximate to the dielectric layer may have a high alloy metal concentration and function to reduce or prevent electromigration of the copper metal. The high alloy metal concentration may further serve as a barrier layer to inhibit copper metal from diffusing into the dielectric layer. A second portion of the graded Cu-alloy seed layer proximate to the trench/via may have a high copper metal concentration to serve as a nucleation site for copper deposition during a subsequent electroplating or electroless plating process, thereby providing adhesion layer functionality.

In accordance with some layered embodiments of the present invention, precursors having single and dual metal centers can be used in a PEALD process to form the Cu-alloy layer. These precursors may also include copper metal (Cu) precursors, which can be used as the main solute. The precursors also include precursors, for example, for manganese metal (Mn) or magnesium metal (Mg), which can be used as the main solvents. This provides Cu-alloy layers such as Cu—Mn and Cu—Mg. In further implementations, other alloy metals may be used including those that do not react or alloy with the underlying liner layer material. Example copper precursors having single metal centers that may be used include Cu(I)acetylacetonate, Cu^{II}(acac)₂ (where acac=acetylacetonato), Cu^{II}(tmhd)₂ (where tmhd=tetramethylheptadienyl), Cu(hfac)₂ (where hfac=hexafluoroacetylacetonate), Cu(thd)₂ (where thd=tetrahydrodionato), Cu(I)phenylacetylide, Cu(II)phthalocyanine, pincer-type complexes of Cu⁵, β-diketimine Cu(I) compounds, bisoxazoline complexes of Cu, diimine complexes of Cu, CpCu(CNMe) (where Cp=cyclopentadienyl and Me=methyl), Cp*CuCO, CpCuPR₃ (where R=Me, ethyl(Et), or phenyl(Ph)), CpCu(CSiMe₃)₂, MeCu(PPh₃)₃, CuMe, CuCCH(ethynylcopper), CuCMe₃(methylacetylidecopper), (H₂C═CMeCC) Cu(3-methyl-3-buten-1-ynylcopper), (H₃CCH═CH)₂CuLi (where Li=lithium cation), Me₃SiCCCH₂Cu, Cu₂Cl₂(butadiene), and N,N′-dialkylacetamidinato Cu compounds where the alkyl group that may be used includes, but is not limited to, isopropyl (iPr), sec-butyl, n-butyl, Me, Et, and linear propyl (n-Pr). Example Mg precursors having single metal centers that may be used in some implementations include CpMn(CO)₃, β-diketimine Mn compounds, nitrosyl Mn (e.g., (pentadienyl)₃Mn₂(NO)₈). In some embodiments of the invention, dual metal center precursors that may be used are organometallic compounds that include both Cu and another metal such as Mn and/or Mg. Example such dual metal center precursors include [(CO)₅Mn(C₆H₅)₂Cu]₂, [CuMn₂R(alkyl)(NCN)₂].

As will be appreciated, a layered alloyed seed layer may be tailored to have a specific composition by manipulating process parameters during the deposition process. For instance, process parameters that may be manipulated to establish a copper metal concentration gradient and/or an Mg or Mn alloy metal concentration gradient within the Cu-alloy layer include the specific precursors that are used in each process cycle (e.g., 5% Mg or Mn), how long each precursor is flowed into the reactor during a process cycle and the precursor concentration and flow rate during each process cycle (e.g., alloy metal precursor pulse duration ranging from 0.5 to 10 seconds with a flow rate of up to 10 standard liters per minute, with the specific number of alloy metal pulses range from 1 to 200 pulses or more depending on the desired thickness of the alloy metal layer), the alloy metal precursor temperature (e.g., between 60 and 250° C.), the vaporizer temperature (e.g., between 60 and 250° C.), the co-reactant used (e.g., hydrogen, a hydrogen plasma, a hydrogen/nitrogen plasma, methane, silane, diborane, and/or germane), how long each co-reactant is flowed into the reactor during a process cycle and the co-reactant concentration and flow rate during each process cycle (e.g., co-reactant pulse duration of between 0.5 and 10 seconds at a flow rate of up to 10 SLM), the sequence or order of the precursor and co-reactant, the co-reactant temperature (e.g., between 80 and 200° C.), the substrate temperature (e.g., between 100 and around 400° C.), the plasma energy applied (e.g., 5 W to 200 W and at a frequency of 13.56 MHz, 27 MHz, or 60 MHz), the pressure within the reaction chamber (e.g., between 0.05 and 3.0 Torr), and the carrier gas composition and flow rate (e.g., argon, xenon, helium, hydrogen, nitrogen, forming gas, or a mixture of these gases, at a flow rate in the range of 100 to around 300 SCCM). Furthermore, changing the parameters of each individual process cycle, or groups of successive process cycles, may also be used to tailor the alloyed seed layer.

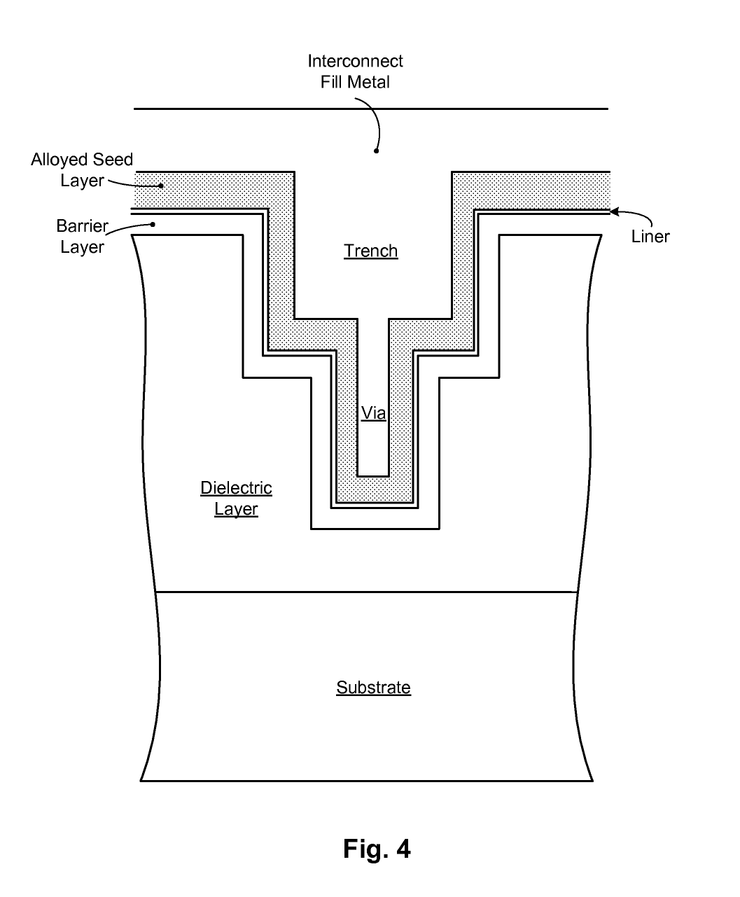

Following the fabrication of the alloyed seed layer, whether formed using a pre-alloyed seed layer or in a layered fashion to provide a homogenous or a graded alloyed seed layer, the structure may be further subjected to a plating or deposition process to fill the trench and via with a desired metal. For example, the structure can be transferred to a reactor containing a plating bath and a plating process may be carried out to deposit an interconnect fill metal, such as a copper, over the alloyed seed layer. FIG. 4 illustrates an interconnect fill metal deposited on the alloyed seed layer to fill the via and trench of the structure of FIG. 3, in accordance with an embodiment of the present invention. In one such example case, electrodeposition is performed on a Cu seed layer alloyed with Mn and/or Mg to plate or otherwise fill the vias and trenches with a fairly pure Cu layer (e.g., greater than 97% Cu). Electrodeposition maybe followed by a small anneal step (e.g., 100-200° C. for 10-60 sec in forming gas). While in some embodiments the plating bath is an electroplating bath and the plating process is an electroplating process, in other embodiments the plating bath can be an electroless plating bath and the plating process is an electroless plating process. Any suitable metal plating (e.g., electro or electroless deposition) or deposition (e.g., PVD, CVD) processes may be used for depositing the interconnect fill metal into the trench and via.

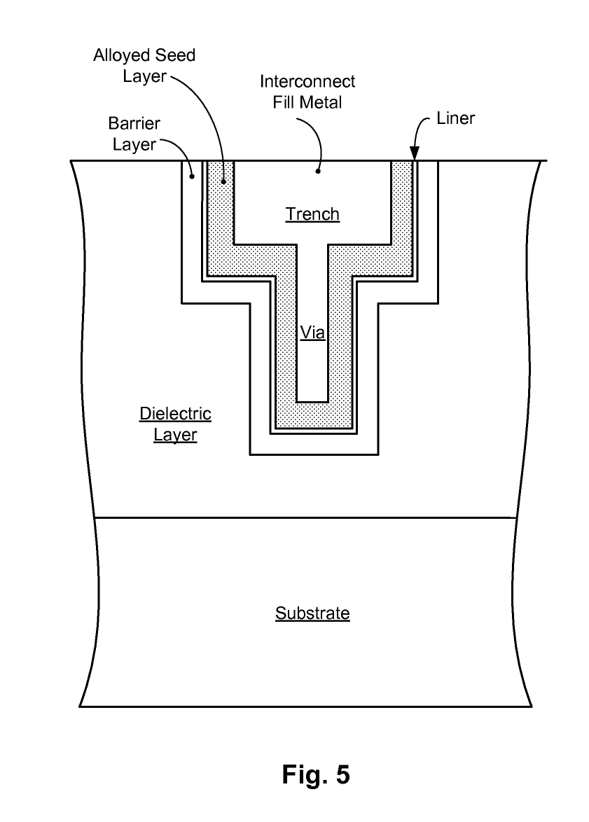

FIG. 5 illustrates planarization of the structure of FIG. 4, in accordance with an embodiment of the present invention. As can be seen in this example, the planarization removes the excess material that is outside the trench and via areas of the interconnect structure, including excess interconnect fill metal (plated or otherwise deposited interconnect metal), alloyed seed layer material, liner material, and barrier layer material. In one such case, the planarization process continues until the dielectric layer is reached, so that only the side walls of the trench and via are covered with the various layers (e.g., interconnect fill metal, alloyed seed layer material, liner material, and barrier layer material). The depth of the planarization can vary and will depend on the desired interconnect structure geometry (e.g., height). The planarization can be carried out, for instance, using one or more CMP processes. Other suitable planarization techniques may be used as well.

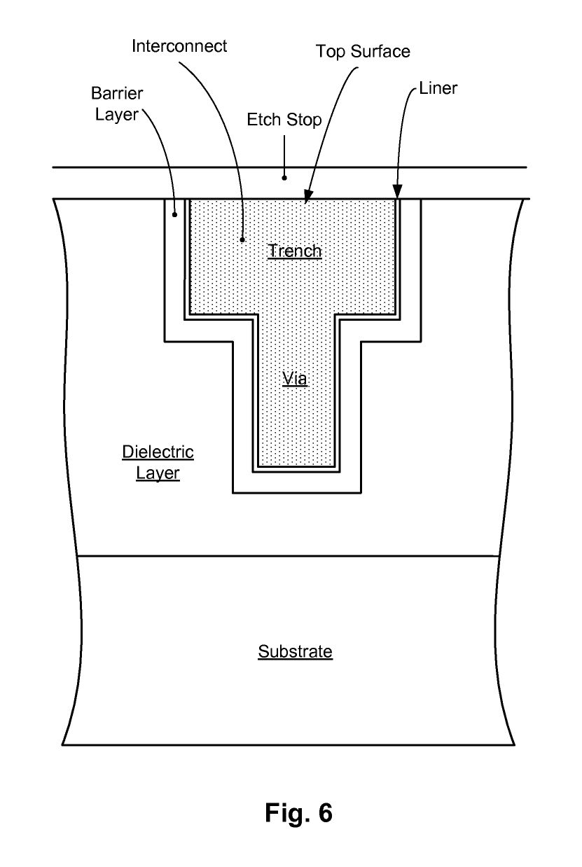

FIG. 6 illustrates formation of an etch stop layer and segregation of dopant material included in the alloyed seed layer into the interconnect fill metal and along the etch stop layer interface the structure of FIG. 5, in accordance with an embodiment of the present invention. The etch stop layer (or other protection layer) can be deposited using any suitable deposition technique (e.g., CVD, PVD, etc). In some example embodiments, the etch stop layer is implemented with silicon nitride, silicon carbide, silicon carbide oxide, silicon carbide nitride, and has a thickness in the range of 10 and 400 nm (e.g. 30 nm to 50 nm). Other suitable protection layer materials will be apparent in light of this disclosure. The protection could be directed to, for example, physical and/or structure support, electrical isolation, and/or oxidation resistance.

As can be seen, the dopant used to alloy the alloyed seed layer effectively segregates or otherwise diffuses away from liner and into the interconnect fill metal, toward the via and trench as well as toward the top surface that interfaces with etch stop layer. As best shown by the tightly spaced dots in FIGS. 3, 4, and 5, the dopant is initially present and concentrated (prior to the segregation/diffusion process) along the sidewalls of the trench and via where it was deposited during seed layer deposition. However, during subsequent heat processing as described herein, and as best shown by the wider spaced dots in FIG. 6, the dopant effectively segregates and diffuses into the interconnect fill metal and along the top surface interface between the Cu line and the etch stop, to provide the interconnect. Depending on the time allowed for application of heat as well as the temperature of the heat, the dopant may segregate or otherwise diffuse to provide a uniform concentration throughout the interconnect that is formed from the alloyed seed layer and interconnect fill metal. As will be appreciated, the dopant has a post-segregation concentration that is lower relative to the pre-segregation concentration that was limited to alloyed seed layer material. Having dopant at the top surface of the interconnect helps improve adhesion between the Cu line and the etch stop dielectric layer (or other layer), which in turn improves electromigration performance of the interconnect structure. Thus, the time and temperature of the dopant segregation process can be adjusted with this in mind. A cross-section view of the structure taken, for example, with a scanning electron microscope (SEM) or transmission electron microscope (TEM) can be used to identify the presence of dopant along this top surface. In some embodiments, the dopant segregation process can be carried out until a uniform dopant concentration exists throughout the interconnect (an equilibrium state is reached). However, other embodiments may utilize a dopant segregation process that does not result in an equilibrium state (partial diffusion). The amount of diffusion can vary depending on factors such as desired dopant content at the top surface of the interconnect structure.

A dopant can diffuse away from the trench sidewalls only if it does not react or form a compound with the underlying layer. In accordance with some embodiments of the invention, Mn and Mg are example dopants that have this property and would be suitable for alloying a Cu seed layer deposited over a Ru liner. In contrast, electromigration dopants that alloy with the liner material or form intermetallics cannot segregate at the top Cu line/etch stop interface. Mn and Mg do not alloy or react with Ru.

Thus, and in accordance with an embodiment of the present invention, dopant segregation is accomplished by subjecting the interconnect structure to an annealing process. The annealing process can vary based on factors such as the interconnect geometries and desired degree of segregation, but in one example case, is carried out at a temperature in the range of 200° C. to 350° C. for 30 to 90 minutes (e.g., 60 minutes) in a forming gas. In one particular example case, the dopant segregation can be brought about during the subsequent etch stop deposition, which can be carried out at high temperature. For instance, the etch stop can be formed with a deposition of silicon nitride layer using a CVD process, wherein the deposition chamber temperature is in the range of 350° C. to 700° C. and the CVD process takes around 15 to 45 minutes. The CVD process provides the thermal budget required for the dopant (e.g., Mg and/or Mn) to sufficiently segregate and otherwise diffuse away from a liner (e.g., Ru) into the interconnect fill metal and towards the top interface between the interconnect (e.g., Cu) and the etch stop (e.g., SiN). Any number of processes can be used to induce the dopant segregation, whether as a result of a dedicated dopant segregation process or as a result of some other process having sufficient thermal budget to induce dopant segregation.

Methodology

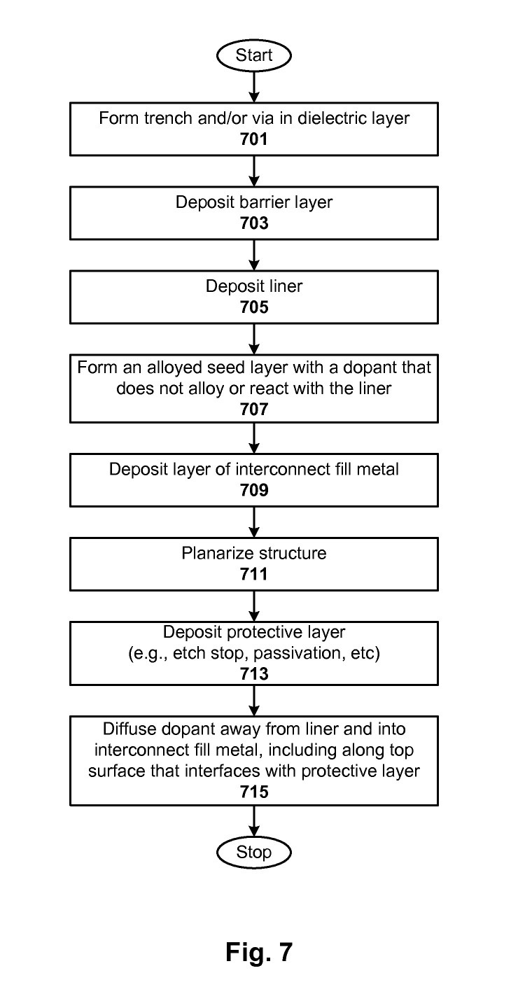

FIG. 7 illustrates a method for forming a dopant enhanced interconnect in accordance with an embodiment of the present invention. The method can be employed for example, to make an interconnect structure such as the example one demonstrated in FIGS. 1 through 6. However, numerous other interconnect configurations can be made, as will be apparent in light of this disclosure.

The method includes forming 701 a trench and/or via in a dielectric layer. As previously explained, the trench and/or via can be formed using standard photolithography (e.g., pattern mask and etch processes) and the dielectric layer may be, for example, deposited on a bulk substrate or on-oxide (e.g., silicon on oxide, or SOI) configuration. Although a dual damascene structure is depicted in FIGS. 1-6, other embodiments can be configured in any desired manner.

In this example case, the method continues with depositing 703 a barrier layer over the trench and/or via. Recall, however, that a barrier layer is optional and that other embodiments may not include a barrier layer. The method continues with depositing 705 a liner over the barrier layer (or over the trench and/or via structure, if no barrier is provided). As previously explained, the barrier layer and/or liner can be deposited using any suitable deposition techniques, such as PVD, CVD or ALD, or a combination of such techniques if so desired. The barrier layer can be implemented, for instance, with tantalum (Ta), tantalum nitride (TaN), titanium (Ti), titanium nitride (TiN), or combinations thereof, and the liner can then be, for example, ruthenium (Ru), cobalt (Co), nickel (Ni), or other material with which the seed layer dopant will not alloy or react, so as to allow for dopant segregation.

The method continues with forming 707 an alloyed seed layer with a dopant that does not alloy or react with the liner. As previously explained, the alloyed seed layer can be formed by depositing a pre-alloyed seed metal, such as Cu alloyed with 5% Mg or Mn. Alternatively, the alloyed seed layer can be formed by depositing alternating layers of seed metal (e.g., Cu) and alloy metal (e.g., Mg or Mn), and then annealing to combine the layers into a homogenous or graded alloyed seed layer.

The method continues with depositing 709 a layer of interconnect fill metal. As previously explained, the fill metal can be deposited with any number of suitable deposition techniques, including electroplating, electroless plating, PVD, CVD, and/or ALD processes. The fill metal can be, for example, relatively pure Cu (e.g., greater than 97% Cu), although other suitable fill metals will be apparent in light of this disclosure. The method continues with planarizing 711 the structure to a desired level (e.g., to dielectric layer). The planarization can be accomplished, for instance, using CMP.

The method continues with depositing 713 a protective layer over the planarized structure. As can be seen, this protective layer can be, for instance, an etch stop or passivation layer, although other protective layers can be implemented as well (e.g., ILD layer, capping layer, etc). Further note that the protective layer may be sacrificial or permanent, depending on particulars of the application of the interconnect structure being fabricated. The method continues with diffusing 715 the dopant away from liner and into interconnect fill metal, including along a top surface of the interconnect that interfaces with the protective layer. As previously explained, this diffusion process can be heat-based, and carried out as a dedicated dopant segregation process or by exploiting the thermal budget of another process (e.g., such as the heat used in depositing the protective layer).

Numerous embodiments and configurations will be apparent in light of this disclosure. For instance, one example embodiment of the present invention provides an interconnect device. The device includes a liner deposited over a trench and/or via structure formed in a dielectric material, and an interconnect (formed on the liner), the interconnect comprising a dopant that does not alloy or react with the liner, wherein the dopant is present at a top surface of the interconnect. The device may include a protective layer deposited on the interconnect along the top surface. The device may include a barrier layer deposited on the trench and/or via such that the liner is deposited on the barrier layer, the barrier layer being implemented with tantalum, tantalum nitride, titanium, titanium nitride, or combinations thereof. In one particular example case, the liner is implemented with ruthenium, cobalt, or nickel. In another particular case, the interconnect is fabricated by applying heat to an alloyed seed layer upon which a layer of interconnect fill metal is deposited. In another particular case, the interconnect is copper alloyed with magnesium and/or manganese.

Another example embodiment of the present invention provides an interconnect device. In this example case, the device includes a barrier layer deposited on a trench and/or via structure formed in a dielectric material. The barrier layer is implemented with tantalum, tantalum nitride, titanium, titanium nitride, or combinations thereof. The device further includes a liner deposited on the barrier layer. The liner is implemented with ruthenium, cobalt, or nickel. The device further includes an interconnect (formed on the liner), the interconnect comprising a dopant that does not alloy or react with the liner, wherein the dopant is present at a top surface of the interconnect. In one specific example case, the interconnect is copper alloyed with magnesium and/or manganese.

Another example embodiment of the present invention provides a method for forming an interconnect device. The method includes depositing a liner over a trench and/or via structure provided in a dielectric material. The method further includes forming (on the liner) an alloyed seed layer comprising a dopant that does not alloy or react with the liner. The method further includes depositing a layer of interconnect fill metal on the alloyed seed layer, and depositing a protective layer on a top surface of the interconnect fill metal, and diffusing the dopant away from the liner toward the top surface of the interconnect fill metal. In one specific example case, prior to depositing a liner, the method includes forming the trench and/or via in the dielectric layer. In another specific example case, prior to depositing a liner, the method includes depositing a barrier layer on the trench and/or via such that the liner is subsequently deposited on the barrier layer, wherein the barrier layer being implemented with tantalum, tantalum nitride, titanium, titanium nitride, or combinations thereof and the liner is implemented with ruthenium, cobalt, or nickel. In another specific example case, prior to depositing a protective layer on a top surface of the interconnect fill metal, the method includes planarizing the device to a desired level. In one specific example case, the layer of interconnect fill metal is applied by a plating process. In another specific example case, forming an alloyed seed layer comprising a dopant that does not alloy or react with the liner includes depositing a pre-alloyed seed metal. In one such case, the pre-alloyed seed metal is copper alloyed with magnesium and/or manganese. In another specific example case, forming an alloyed seed layer comprising a dopant that does not alloy or react with the liner includes depositing alternating layers of seed metal and alloy metal, and then annealing to combine the layers into a homogenous or graded alloyed seed layer. In one such case, the seed metal is copper and the alloy metal is magnesium and/or manganese. In another specific example case, diffusing the dopant away from the liner is a dedicated dopant segregation process. In another specific example case, diffusing the dopant away from the liner is carried out by exploiting thermal budget of a process included in forming the interconnect device. In one such case, depositing a protective layer on a top surface of the interconnect fill metal provides the thermal budget.

The foregoing description of example embodiments of the invention has been presented for the purposes of illustration and description. It is not intended to be exhaustive or to limit the invention to the precise forms disclosed. Many modifications and variations are possible in light of this disclosure. It is intended that the scope of the invention be limited not by this detailed description, but rather by the claims appended hereto.

What is claimed is:

1. An interconnect device, comprising:
a liner deposited over a trench and/or via structure formed in a dielectric material; and
an interconnect, formed on the liner, the interconnect comprising a dopant that does not alloy or react with the liner, wherein the dopant is present at a top surface of the interconnect.

2. The device of claim 1, further comprising:
a protective layer deposited on the interconnect along the top surface.

3. The device of claim 1, further comprising:
a barrier layer deposited on the trench and/or via such that the liner is deposited on the barrier layer, the barrier layer being implemented with tantalum, tantalum nitride, titanium, titanium nitride, or combinations thereof.

4. The device of claim 1 wherein the liner is implemented with ruthenium, cobalt, or nickel.

5. The device of claim 1 wherein the interconnect is fabricated by applying heat to an alloyed seed layer upon which a layer of interconnect fill metal is deposited.

6. The device of claim 1 wherein the interconnect is copper alloyed with magnesium and/or manganese.

7. An interconnect device, comprising:
a barrier layer deposited on a trench and/or via structure formed in a dielectric material, the barrier layer being implemented with tantalum, tantalum nitride, titanium, titanium nitride, or combinations thereof;
a liner deposited on the barrier layer, wherein the liner is implemented with ruthenium, cobalt, or nickel; and
an interconnect, formed on the liner, the interconnect comprising a dopant that does not alloy or react with the liner, wherein the dopant is present at a top surface of the interconnect.

8. The device of claim 7 wherein the interconnect is copper alloyed with magnesium and/or manganese.

9. A method for forming an interconnect device, the method comprising:
depositing a liner over a trench and/or via structure provided in a dielectric material;
forming, on the liner, an alloyed seed layer comprising a dopant that does not alloy or react with the liner;
depositing a layer of interconnect fill metal on the alloyed seed layer;
depositing a protective layer on a top surface of the interconnect fill metal; and
diffusing the dopant away from the liner toward the top surface of the interconnect fill metal.

10. The method of claim 9 wherein prior to depositing a liner, the method comprises:
forming the trench and/or via in the dielectric layer.

11. The method of claim 9 wherein prior to depositing a liner, the method further comprises:
depositing a barrier layer on the trench and/or via such that the liner is subsequently deposited on the barrier layer, wherein the barrier layer being implemented with tantalum, tantalum nitride, titanium, titanium nitride, or combinations thereof and the liner is implemented with ruthenium, cobalt, or nickel.

12. The method of claim 9 wherein prior to depositing a protective layer on a top surface of the interconnect fill metal, the method comprises:
planarizing the device to a desired level.

13. The method of claim 9 wherein the layer of interconnect fill metal is applied by a plating process.

14. The method of claim 9 wherein forming an alloyed seed layer comprising a dopant that does not alloy or react with the liner comprises depositing a pre-alloyed seed metal.

15. The method of claim 14 wherein the pre-alloyed seed metal is copper alloyed with magnesium and/or manganese.

16. The method of claim 9 wherein forming an alloyed seed layer comprising a dopant that does not alloy or react with the liner comprises depositing alternating layers of seed metal and alloy metal, and then annealing to combine the layers into a homogenous or graded alloyed seed layer.

17. The method of claim 16 wherein the seed metal is copper and the alloy metal is magnesium and/or manganese.

18. The method of claim 9 wherein diffusing the dopant away from the liner is a dedicated dopant segregation process.

19. The method of claim 9 wherein diffusing the dopant away from the liner is carried out by exploiting thermal budget of a process included in forming the interconnect device.

20. The method of claim 19 wherein depositing a protective layer on a top surface of the interconnect fill metal provides the thermal budget.
